(19) United States
(12) Patent Application Publication
(10) Pub. No.: US 2011/0135840 A1
(43) Pub. Date: Jun. 9, 2011

(54) METHOD FOR PRODUCING A COMPONENT THROUGH SELECTIVE LASER MELTING AND PROCESS CHAMBER SUITABLE THEREFOR

(76) Inventors: Christian Doye, Berlin (DE); Sven Pyritz, Berlin (DE); Uwe Pyritz, Berlin (DE); Martin Schäfer, Berlin (DE)

(21) Appl. No.: 12/737,275

(22) PCT Filed: Jun. 17, 2009
(86) PCT No.: PCT/EP2009/057514

§ 371 Date: Feb. 17, 2011

(30) Foreign Application Priority Data
Jun. 26, 2008 (DE) 10 2008 030 186.8

(51) Int. Cl. B05D 3/06; C23C 16/50

(52) U.S. Cl. 427/554; 118/723 R

(57) ABSTRACT

A component is produced through selective laser melting of a powder material in a process chamber using a laser which is also used for producing coating areas of the component. The coating areas have a composition that differs from the composition of the powder material. This is accomplished by intermittently introducing a reactive gas that reacts with the powder material or that produces a material on the component from the precursors present in the reactive gas. In the process chamber, a feed line may be provided for introducing the reactive gas close to the laser.

### CROSS REFERENCE TO RELATED APPLICATIONS

This application is the U.S. national stage of International Application No. PCT/EP2009/057514, filed Jun. 17, 2009 and claims the benefit thereof. The International Application claims the benefits of German Application No. 102008030186.8 filed on Jun. 26, 2008, both applications are incorporated by reference herein in their entirety.

### BACKGROUND

Described below is a method for producing a component through selective laser melting, in which the component is produced by a laser beam, in layers, from a powder by material particles being melted on.

A method of the type initially specified may be gathered, for example, from DE 102 23 796 C1. Accordingly, it is possible through selective laser melting, for example, to produce complex three-dimensional structures which have a large surface in relation to the material expended. These structures may also be in the form of a catalyst, in that they are obtained from catalytic material by laser melting. However, in this method, it must be borne in mind that the mechanical properties of catalyst materials are often inferior to those of conventional construction materials, therefore this has to be taken into account, for example, in the determination of the wall thicknesses.

### SUMMARY

A method is described below for producing a component through selective laser melting, by which even complex requirement profiles in terms of both mechanical properties and other properties (for example, catalytic functions) can be fulfilled in a satisfactory way.

In the method initially mentioned, selective laser melting is also used in order, by employing a temporarily supplied reactive gas, to produce locally, on the component obtained, layer regions with a composition deviating from that of the material of the component, in that the reactive gas is incorporated into the layer regions which are being formed. It is thereby advantageously possible, by suitable selection of the material particles, to provide a construction material which has high mechanical stability and is therefore suitable for many different applications. In particular, for example, even filigree three-dimensional structures can thereby be produced at minimum outlay in terms of material. On the other hand, by a suitable reactive gas being selected, it can be ensured that, during the production of the component, layer regions arise which can ensure particular functions of the component. These include, for example, layer regions composed of a catalytic material, so that the component can be used, for example, in chemical process engineering. Other applications would be, for example, structures which are employed for catalytic air purification (ozone filters).

According to one refinement, there is provision whereby the layer regions are applied as the last ply or last plies to the component. This takes place in such a way that a closed surface layer is obtained on the component.

As a result, for example, seals of components, that is to say closed surface layers which, for example, can afford protection for the component, can be produced. For example, it is conceivable to produce a component with a hardened surface, and the reactive gases supplied may be nitrogen or oxygen which react with the material of the metallic material particles.

So that surface regions of the component to be produced can also be provided with a surface layer lying on that side of the component to be produced which faces away from the laser beam, according to another refinement it is also possible that the layer regions are applied as a first ply or first plies to a component so that a closed surface layer is formed on this side. This surface layer can assume the same functions as have already been explained.

The thickness of the surface layer depends on the number of first or last plies produced, using the reactive gas. To be precise, the thickness of a ply produced is limited as a consequence of the process of selective laser melting, and therefore thicker layers can be produced only by producing several plies.

In another refinement, after the layer regions have been produced, further plies of the component, which are composed solely of the material, are deposited on these layer regions, the latter forming an intermediate layer. This may be advantageous when the properties of the component produced are also to be dependent upon layer regions inside the component. It is conceivable, for example, to produce a wear indicator layer as an intermediate layer which has a conspicuously different color from that of the component. This may be achieved, for example, by different ceramic materials. The wear indicator then functions such that a color change of the component surface is conspicuous as soon as the regions of the component which lie above the intermediate layer are eroded. These layer regions can then be applied to the component again, for example, by renewed selective laser melting, in order to allow it to be reused.

An especial refinement is obtained when the component produced is a grid-like structure which has undercuts with respect to the beam direction of the laser beam. In this case, the layer regions are in each case produced even before, as the component continues to arise, the occurrence of the undercut would prevent the laser beam from having access to these layer regions. In this variant of the method, the advantages of producing a layer region in the same process as the production of the component become especially clear. Almost any desired three-dimensional structures can be produced, in which special layer regions are to be provided even in regions which are accessible with difficulty or are inaccessible after the production of the component. This is especially advantageous for components which are used in processes as a catalyst. To be precise, catalytic efficiency depends on the available surface. Thus, in the component produced, the catalytic function is performed by the layer regions produced. These may be distributed in complex three-dimensional grid structures, these giving rise to a fluid reaction, for example, due to a forced throughflow of a fluid.

Basically, in particular, two formation mechanisms may be envisaged for producing the layer regions. According to one refinement of the method, therefore, there is provision whereby the reactive gas has a composition such that it reacts with the melted-on material particles. Such gases may be, for example, oxygen, nitrogen or a mixture of these two gases. Owing to the temperature prevailing at the laser melting baths used for selective laser melting, reaction of the material with the reactive gas takes place, so that the latter is incorporated into the layer region which arises.

As a result, for example, nitridic or oxidic or oxynitridic ceramics can be produced, which have outstanding catalytic properties.

Another possibility is, advantageously, that for the reaction, that is to say the production of the layer regions, the reactive gas contains precursors of the material of the layer region to be produced. In this case, experimental knowledge may be resorted to, which is already known in connection with what is known as laser CVD. In laser CVD, precursors of the layer material to be produced are mixed to form a reactive gas (that is to say, these precursors are themselves gaseous) and are deposited on the surface by the laser beam. In this case, specific process windows, for example with regard to the temperature prevailing on the surface, have to be taken into account, which, in terms of specific material combinations, can be gathered from general literature. Examples of some of these reactive gases, together with the process parameters mentioned, are listed in the following table.

| Process temperature | Layer material | Precursors |
|---|---|---|
| 800° C. | SiC | CH₄/H₂/SiH₄ |
| 900° C. | W | H₂/WF₆ |
| 950° C. | TiN | N₂/H₂/TiCl₄ |
| 1000° C. | TiC, TiB₂ or Al₂O₃ | CH₄/H₂/TiCl₄, BCl₃/H₂/ |
| | | TiCl₄, CO₂/H₂/AlCl₃ |
| 1100° C. | Si | H₂/HSiCl₃ |
| 1200° C. | Si₃N₄ | NH₃/H₂/SiCl₃ |

The process chamber for selective laser soldering has a process space closed off hermetically with respect to the surroundings and having a reception plate for producing a component.

This process space possesses, moreover, an inlet and an outlet for an inert gas which is intended to avoid unwanted reactions of the melting bath. Alternatively, the outlet may also serve for evacuating the process space.

A process chamber of this type is described, for example, in DE 198 53 947 C1. This process chamber has the features mentioned, argon being pumped as inert gas through the inlet and the outlet. Furthermore, the process chamber has, in the region of a window for the laser beam, further inlets through which helium can be injected into the process chamber. In the region of the window, this helium displaces the argon and, where appropriate, vapors of the melted-on material powder which are contained in it and which would contaminate this window.

Accordingly, there is provision whereby a feed for a reactive gas is provided in addition to the inlet and the outlet. In contrast to the feeds according to DE 198 53 947 C1, therefore, a container is connected to the feed and contains a reactive gas, but no inert gas. Moreover, the feed must take place such that the reactive gas does not displace the inert gas in the region of the window, but, instead, in the region of the component surface just produced. The reason for this may be that a reaction with the reactive gas at the moment when the layer regions are produced is even desirable and therefore runs counter to the aim, pursued by the inert gas, after preventing reaction of the material of the component. By use of the additional inlet, however, it is possible to optimize the process flow, since a constant complete exchange of the inert gas and of the reactive gas is not necessary. Instead, for the period of time when the layer regions are being produced, the reactive gas is fed into the reaction chamber such that a reaction can take place on the surface. As soon as the introduction of the reactive gas is stopped, the inlet gas flushes the reactive gas residues away from the component surface, so that the component material arising is protected from reactions again.

It is therefore advantageous if the issue of the feed lies nearer to the reception plate, as compared with the inlet. It is thereby possible, with minimal outlay in terms of reactive gas, to achieve a comparatively high degree of action upon the component surface obtained. It is especially advantageous if the issue of the feed can be moved in a plane parallel to the reception plate. It must be noted, in this regard, that the plies from which the component is produced likewise in each case run parallel to the reception plate, since the latter is lowered ply for ply, in order to make it possible to produce the component in layers in a specific plane. If the feed can be moved in a plane lying just above this, introduction of the reactive gas can be further optimized. To be precise, it is possible to bring the introduction of reactive gas into the vicinity of the melting bath produced by the laser beam, so that optimal efficiency of the reactive gas used becomes possible there.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a schematic cross section of an exemplary embodiment of the process space,

FIGS. 2 and 3 are cross sections illustrating details of exemplary embodiments of components, and

FIGS. 4 to 9 are cross sections illustrating selected phases of an exemplary embodiment of the method.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

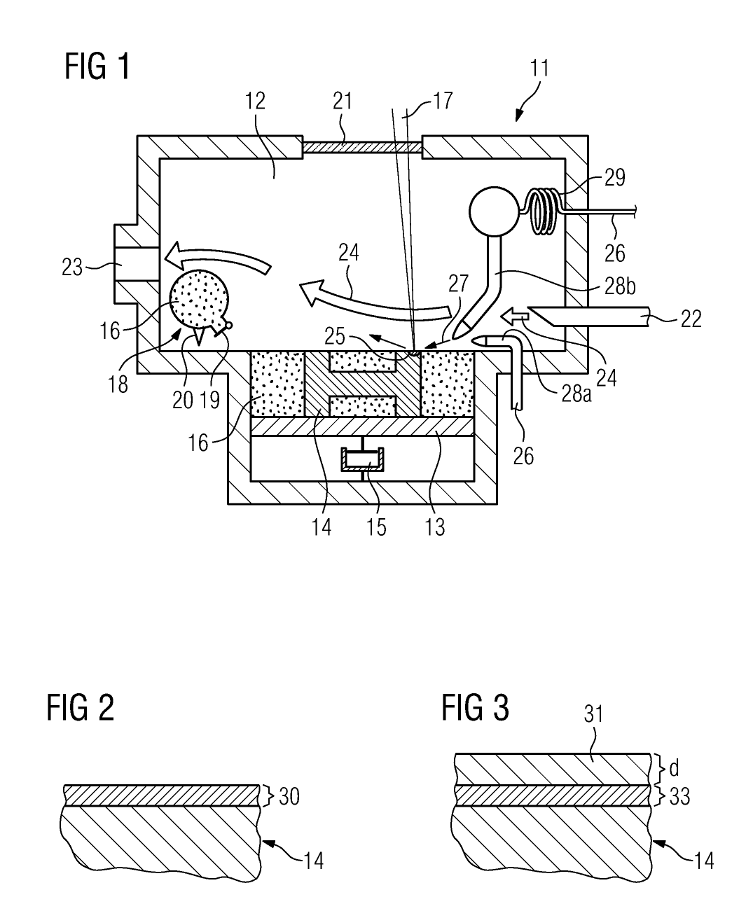

A process chamber 11 according to FIG. 1 has a process space 12 in which a plate 13 for a component 14 to be produced is provided. This reception plate can be lowered by an actuator 15, so that the component 14 can be produced in a stock of powder 16 of the material for the component, while, in each case after a ply of the component 14 has been produced by a laser beam 17, the reception plate 13 is lowered by the amount of the thickness of the ply. A movable stock container 18 with a metering flap 19 and with a doctor blade 20 can be moved over and above the stock container in a way not illustrated in any more detail, with the result that, after the lowering of the reception plate 13, a further ply of powder can be applied to the ply of the component 14 can be produced.

The laser is accommodated outside the process chamber 11 and is not illustrated in any more detail. The process chamber has a window 21 through which the laser beam finds its way into the process chamber. Furthermore, the process chamber has an inlet 22 and an outlet 23 which makes it possible to conduct a process gas through the process chamber according to the broad arrows 24 indicated. This inert gas sweeps over the surface of the component 14, prevents unwanted reactions of the melting bath 25 of component material with gaseous constituents and discharges possible evaporation products of the component material through the outlet 23.

In addition, a feed 26 is provided, through which a reactive gas can be fed according to the narrow arrows 27. As already described, the reactive gas causes the formation of a layer region (cf., for example, FIG. 2) with a composition deviating from that of the component material. The feed 26 is illustrated in two alternatives according to FIG. 1. It may be formed by a stationary nozzle 28a, the issue of which is arranged in such a way that the reactive gas is conducted in closest proximity over the component 14 being produced. There is, however, also a possibility of providing a nozzle 28b moveably in such a way that it can be moved parallel to the reception surface and can therefore be moved into the immediate vicinity of the melting bath 25. For this purpose, an elastic feed hose 29 is provided for the reactive gas.

According to FIG. 2, an exemplary embodiment of the component 14 is illustrated. This has a surface layer 30 as a layer region with a composition deviating from the component composition. This surface layer may be composed, for example, of titanium nitride, the component 14 composed of titanium being used as a tool.

According to FIG. 3, the layer region is in the form of an intermediate layer 33. That fraction of the component material which forms the surface 31 has a thickness d which corresponds exactly to the permissible abrasive overall wear of the component. When this region of the component is eroded, the surface of the intermediate layer 31 appears, which may be detected, for example, by a color change of the surface.

For this purpose, the intermediate layer therefore requires a different color from the component.

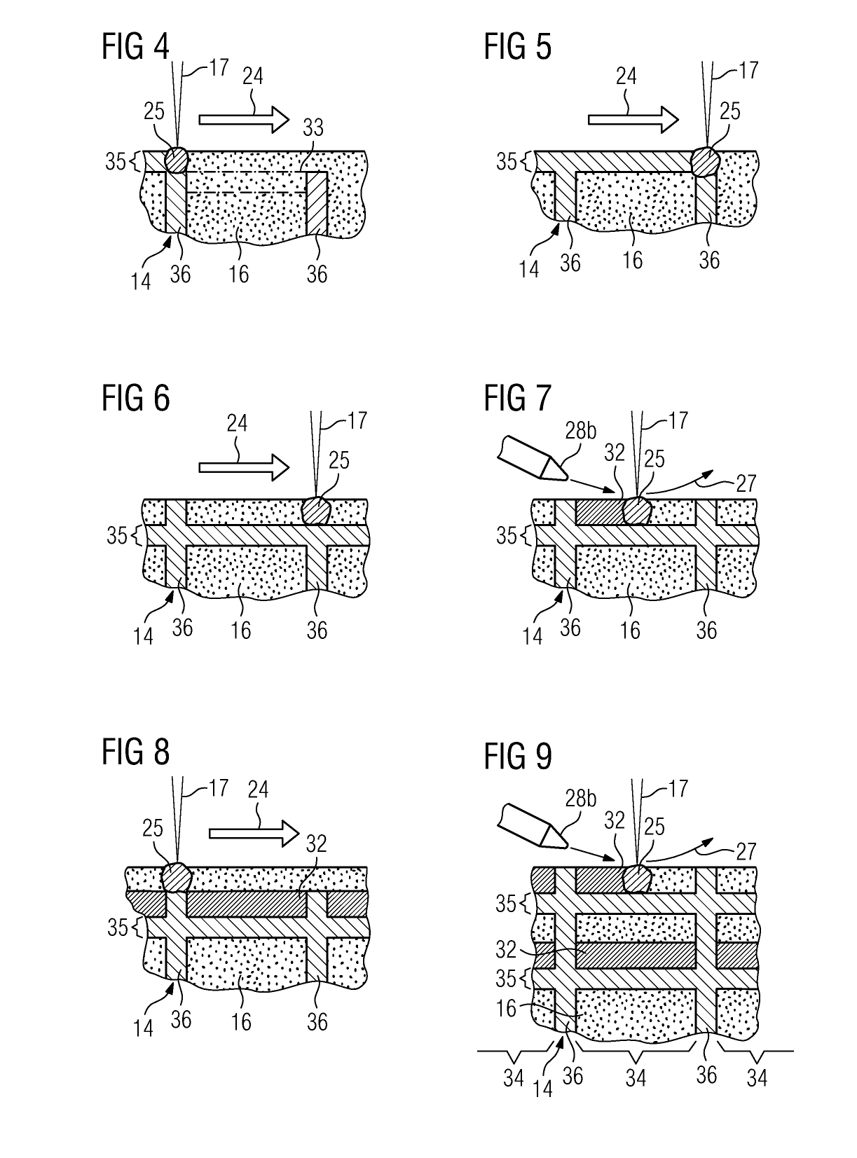

FIGS. 4 to 9 illustrate various phases in the generation of the component 14 which forms a three-dimensional grid with layer regions 32 which have catalytic properties. As may be gathered from FIG. 9, the three-dimensional grid structure has abundant undercuts 34 on account of its spatial orientation, as seen in the direction of the laser beam 17. Undercut means, in this case, that the laser beam 17 can no longer have access to the undercut component regions after the structures lying above them have been produced.

The spatial structure of the grid-shaped component 14 may be imagined as being formed by alternating planes 35 which serve as a substrate for the layer regions 32, columns 36 which in each case connect adjacent planes then being made, which ensure that cavities arise between the planes 35. During the manufacturing process, these cavities are also filled by the powder 16. The finished structure may serve, for example, as a catalyst, in which case a fluid flows through it perpendicularly with respect to the drawing plane.

FIG. 4 shows a phase in which the columns 36 are finished. A ply which forms a new plane 35 in the finished structure is just produced. This ply then lies on the finished columns 36 (and, optionally, on a previously produced layer region 33).

FIG. 5 illustrates how the plane 35 being formed already connects two adjacent columns 36 to one another.

In FIG. 6, the first ply on the newly provided plane 35 is produced. First, under the influence of the inert gas 24, column stubs 36 for the new columns 36 are manufactured in the ply. As may be gathered from FIG. 7, reactive gas 27 is subsequently conducted over the surface of the current ply by the nozzle 28b, and, with the aid of the laser, a layer region 32 having catalytic properties is produced on the plane 35 outside the column stubs 36.

FIG. 8 illustrates how, in the plies following the layer regions 32, in each case only the column stubs for the new columns 36 are built up by one “story”.

It may gathered from FIG. 9, as compared with FIG. 8, that a further three plies have been applied. In the first ply, the columns 36 have been lengthened once again (here, optionally, a layer region 33 could also be produced again in a similar way to that shown in FIG. 1). In the second ply, a new plane 35 has been produced, and in the third ply, which is currently being processed, the operations illustrated in FIGS. 6 and 7 are repeated. Thus, the three-dimensional grid can be extended, as desired, until the structure has reached the desired dimensions

The system also includes permanent or removable storage, such as magnetic and optical discs, RAM, ROM, etc. on which the process and data structures of the present invention can be stored and distributed. The processes can also be distributed via, for example, downloading over a network such as the Internet. The system can output the results to a display device, printer, readily accessible memory or another computer on a network.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-11. (canceled)

12. A method for producing a component through selective laser melting, comprising:
using a laser beam to produce the component in layers, from a powder by material particles being melted on; and
selective laser melting, using a temporarily supplied reactive gas, to produce locally, on the component, layer regions with a composition deviating from that of the material particles melted in forming the component, by incorporating the reactive gas into the layer regions during formation thereof.

13. The method as claimed in claim 12, wherein the layer regions are applied, as a final ply or final plies of the component, to form a closed surface layer of the component.

14. The method as claimed in claim 12, further comprising, after the layer regions have been produced, depositing further plies of the component composed solely of the material particles, on the layer regions to thereby form an intermediate layer of the layer regions.

15. The method as claimed in claim 12, wherein the layer regions are applied, as a first ply or first plies of the component, to form a closed surface layer of the component.

16. The method as claimed in claim 12, wherein the component produced has a grid-like structure with undercuts with respect to a beam direction of the laser beam, the layer regions in each case being produced before, as the component continues to arise, the occurrence of the undercuts preventing the laser beam from having access to the layer regions.

17. The method as claimed in claim 16, wherein the reactive gas has a composition that reacts with the material particles melted to form the component.

18. The method as claimed in claim 16, wherein the reactive gas contains precursors of a layer material of the layer regions.

19. The method as claimed in claim 18, further comprising controlling temperature required for reaction of the precursors by introduction of energy by the laser beam.

20. A process chamber, in surroundings, for selective laser melting to produce a component, comprising:
chamber walls hermetically sealing a process space with respect to the surroundings and having an inlet for an inert gas and an outlet for evacuating the process space;
a reception plate to support a component; and
a feed for a reactive gas.

21. The process chamber as claimed in claim 20, wherein the feed has an output nearer to the reception plate than the inlet is to the reception plate.

22. The process chamber as claimed in claim 21, further comprising a movement apparatus to move the output of the feed in a plane parallel to the reception plate.
